(19) United States
(12) Patent Application Publication
(10) Pub. No.: US 2023/0378918 A1
(43) Pub. Date: Nov. 23, 2023

(54) AMPLIFIER CIRCUIT AND COMMUNICATION DEVICE

(71) Applicant: Murata Manufacturing Co., Ltd., Kyoto (JP)

(72) Inventors: Daisuke WATANABE, Kyoto (JP); Naoki MORIKAWA, Kyoto (JP)

(21) Appl. No.: 18/309,089

(22) Filed: Apr. 28, 2023

(30) Foreign Application Priority Data
May 20, 2022 (JP) 2022-083236

(51) Int. Cl. H03F 3/00; H03F 1/56; H03H 9/64; H03F 3/195

(52) U.S. Cl. CPC H03F 3/005; H03F 1/565; H03H 9/64; H03F 3/195; H03F 2200/294

(57) ABSTRACT

An amplifier circuit includes a low noise amplifier disposed in an amplification path, switches connected in series to a bypass path bypassing the low noise amplifier, a capacitor having at least one end connected between the switches in the bypass path, and a switch connected between the bypass path and a ground. The switch connected between the bypass path and the ground is connected between the other switches.

### CROSS REFERENCE TO RELATED APPLICATION

This application claims priority from Japanese Patent Application No. 2022-083236 filed on May 20, 2022. The content of this application is incorporated herein by reference in its entirety.

### BACKGROUND ART

The present disclosure relates to an amplifier circuit and a communication device.

Japanese Unexamined Patent Application Publication No. 2021-35016 discloses an amplifier circuit including an amplification path and a bypass path. The amplification path includes an amplifier, and the bypass path bypasses the amplifier. A plurality of switches are disposed in each of the amplification path and the bypass path. Japanese Unexamined Patent Application Publication No. 2021-35016 discloses that the isolation characteristics between the amplification path and the bypass path are improved by turning on and off each switch.

### BRIEF SUMMARY

However, the amplifier circuit disclosed in Japanese Unexamined Patent Application Publication No. 2021-35016 has a problem in that it is not possible to sufficiently achieve impedance matching when the bypass path is used, and a signal loss occurs.

The present disclosure provides an amplifier circuit and a communication device capable of reducing a signal loss.

An amplifier circuit according to an aspect of the present disclosure includes an amplifier disposed in a first path, a first switch and a second switch connected in series to a second path bypassing the amplifier, a first capacitor having at least one end connected between the first switch and the second switch in the second path, and a third switch connected between the second path and a ground. The third switch is connected between the first switch and the second switch.

A communication device according to an aspect of the present disclosure includes the amplifier circuit according to the above aspect and a radio frequency (RF) signal processing circuit that processes a high-frequency signal transmitted through the amplifier circuit.

According to the present disclosure, the signal loss can be reduced.

### BRIEF DESCRIPTION OF THE DRAWINGS

FIG. 1 is a circuit configuration diagram of an amplifier circuit and a communication device according to an embodiment;

FIG. 2 is a circuit configuration diagram illustrating a circuit state of an amplification mode of the amplifier circuit according to the embodiment; and

FIG. 3 is a circuit configuration diagram illustrating a circuit state of a bypass mode of the amplifier circuit according to the embodiment.

### DETAILED DESCRIPTION

Hereinafter, an amplifier circuit and a communication device according to embodiments of the present disclosure will be described in detail with reference to the drawings. Note that each of the embodiments described below illustrates a specific example of the present disclosure. Accordingly, the numerical values, shapes, materials, structural elements, the arrangement and connection of the structural elements, steps, the processing order of the steps, and the like described in the following embodiments are mere examples, and are not intended to limit the present disclosure. Therefore, among the structural elements in the following embodiments, structural elements not recited in any of the independent claims are described as optional structural elements.

Each drawing is a schematic view and is not necessarily strictly illustrated. Therefore, for example, the scales and the like in the drawings are not necessarily the same. In the drawings, substantially the same components are denoted by the same reference numerals, and redundant description thereof will be omitted or simplified.

In this specification, the term “connected” includes not only a case of direct connection by a connection terminal and/or a wiring conductor but also a case of electrical connection via another circuit element. In addition, the expression “connected between A and B” means connection to both A and B between A and B. Furthermore, in this specification, the expression “connected in series to a path” means connection in series between an input terminal and an output terminal of the path. For example, the expression “C and D connected in series to a path” means that C and D are connected in series between an input terminal and an output terminal of the path.

In this specification, unless otherwise specified, ordinal numbers such as “first” and “second” do not denote the number or the order of structural elements and are used for the purpose of avoiding confusion among structural elements of the same kind and distinguishing them.

In this specification, a “transmission path” means a transmission line including a wiring for transmitting a high-frequency transmission signal, an electrode directly connected to the wiring, a terminal directly connected to the wiring or the electrode, or the like. In addition, a “reception path” means a transmission line including a wiring for transmitting a high-frequency reception signal, an electrode directly connected to the wiring, a terminal directly connected to the wiring or the electrode, or the like. Furthermore, a “transmission/reception path” means a transmission line including a wiring for transmitting both a high-frequency transmission signal and a high-frequency reception signal, an electrode directly connected to the wiring, a terminal directly connected to the wiring or the electrode, or the like. Furthermore, a “path connecting A and B” means a transmission path that includes both ends of “A” and “B” and connects “A” and “B”.

### Embodiments

### 1. Configurations of Amplifier Circuit 1 and Communication Device 4

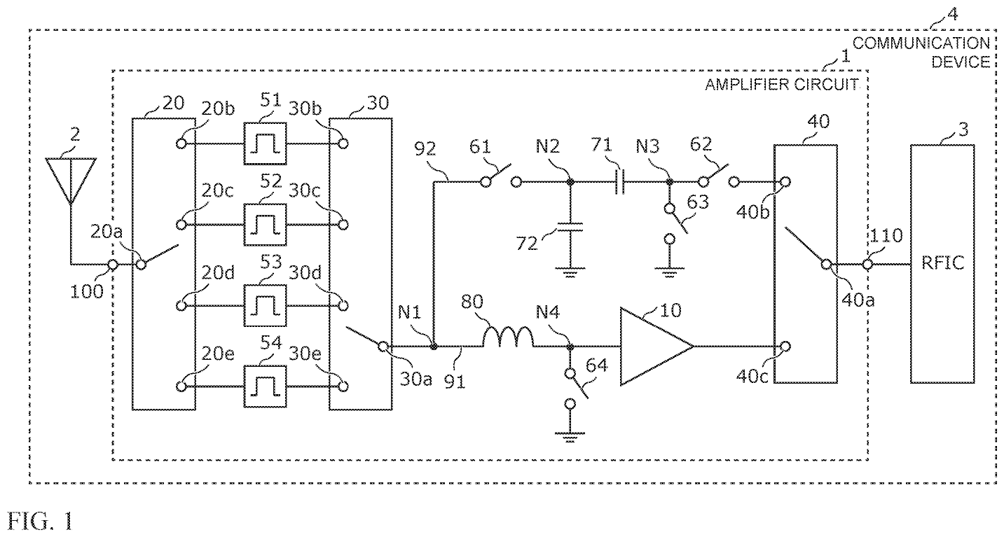

The circuit configurations of an amplifier circuit 1 and a communication device 4 according to the present embodiment will be described with reference to FIG. 1. FIG. 1 is a circuit configuration diagram of the amplifier circuit 1 and the communication device 4 according to the present embodiment.

### 1.1 Circuit Configuration of Communication Device 4

First, the circuit configuration of the communication device 4 according to the present embodiment will be described. The communication device 4 illustrated in FIG. 1 is a device used in a communication system, and is, for example, a mobile terminal such as a smartphone or a tablet computer. As illustrated in FIG. 1, the communication device 4 includes the amplifier circuit 1, an antenna 2, and a radio frequency (RF) signal processing circuit (RFIC) 3.

The amplifier circuit 1 transmits a high-frequency signal between the antenna 2 and the RFIC 3. In the present embodiment, the amplifier circuit 1 transmits a reception signal, which is an example of a high-frequency signal, but the present disclosure is not limited thereto. The amplifier circuit 1 may transmit a transmission signal, which is an example of a high-frequency signal. A detailed circuit configuration of the amplifier circuit 1 will be described later.

The antenna 2 is connected to an antenna connection terminal 100 of the amplifier circuit 1, receives a high-frequency signal from the outside, and outputs the high-frequency signal to the amplifier circuit 1. The antenna 2 may also transmit a high-frequency signal output from the amplifier circuit 1.

The RFIC 3 is an example of a signal processing circuit that processes a high-frequency signal. Specifically, the RFIC 3 performs signal processing on a reception signal input via a reception path of the amplifier circuit 1 by down-conversion or the like, and outputs the reception signal generated through the signal processing to a baseband signal processor circuit (BBIC, not illustrated). The RFIC 3 may also perform signal processing on a transmission signal input from the BBIC by up-conversion or the like, and output the transmission signal generated through the signal processing to a transmission path of the amplifier circuit 1. In addition, the RFIC 3 includes a control unit that controls a switch, an amplifier, a bias circuit, and the like included in the amplifier circuit 1. The control unit of the RFIC 3 controls, for example, a power supply voltage and a bias voltage supplied to each amplifier included in the amplifier circuit 1.

A part or all of the functions as the control unit of the RFIC 3 may be implemented outside the RFIC 3, and may be implemented in the BBIC or the amplifier circuit 1, for example.

The circuit configuration of the communication device 4 illustrated in FIG. 1 is an example, and is not limited thereto. For example, the antenna 2 may be omitted from the communication device 4. Alternatively, a plurality of antennas 2 may be provided in the communication device 4.

### 1.2 Circuit Configuration of Amplifier Circuit 1

Next, the circuit configuration of the amplifier circuit 1 according to the present embodiment will be described.

As illustrated in FIG. 1, the amplifier circuit 1 includes a low noise amplifier 10, switch circuits 20, 30, and 40, filters 51, 52, 53, and 54, switches 61, 62, 63, and 64, capacitors 71 and 72, and an inductor 80. The amplifier circuit 1 includes an amplification path 91, a bypass path 92, the antenna connection terminal 100, and a high-frequency output terminal 110.

The antenna connection terminal 100 is an input terminal of the amplifier circuit 1 and is connected to the antenna 2. A reception signal received by the antenna 2 is input to the antenna connection terminal 100.

The high-frequency output terminal 110 is an output terminal of the amplifier circuit 1, and is connected to the RFIC 3. A reception signal transmitted through the amplifier circuit 1 is output from the high-frequency output terminal 110.

In the amplifier circuit 1, a high-frequency signal (reception signal) input to the antenna connection terminal 100 is output from the high-frequency output terminal 110 through one of the amplification path 91 and the bypass path 92. In other words, the amplifier circuit 1 includes the amplification path 91 and the bypass path 92 as transmission paths of a high-frequency signal.

The amplification path 91 is an example of a first path, and the low noise amplifier 10 is disposed therein. In the present embodiment, the amplification path 91 is a path connecting a terminal 30a of the switch circuit 30 and a terminal 40c of the switch circuit 40. If the switch circuits 30 and 40 are not provided, the amplification path 91 may be regarded as a path connecting a node N1 and the output of the low noise amplifier 10. The node N1 is a branch point between the amplification path 91 and the bypass path 92.

An input terminal of the amplification path 91 can be regarded as the node N1, the terminal 30a, or a given position on a path connecting the node N1 and the terminal 30a. An output terminal of the amplification path 91 can be regarded as an output end of the low noise amplifier 10, the terminal 40c, or a given position on a path connecting the output end of the low noise amplifier 10 and the terminal 40c.

The bypass path 92 is an example of a second path and is a path bypassing the low noise amplifier 10. That is, the bypass path 92 is a path for outputting the high-frequency signal (reception signal) transmitted through the amplifier circuit 1 without necessarily passing through the low noise amplifier 10. The bypass path 92 is connected in parallel to the low noise amplifier 10 in the amplification path 91.

Specifically, the bypass path 92 is a path that connects the node N1 and a terminal 40b of the switch circuit 40. The node N1 may be the terminal 30a of the switch circuit 30. If the switch circuit 40 is not provided, the bypass path 92 may be regarded as a path connecting the node N1 and an end portion (an end portion opposite to an end portion on the node N1 side) of the switch 62. An input terminal of the bypass path 92 is the node N1. An output terminal of the bypass path 92 can be regarded as the end portion (the end portion opposite to the end portion on the node N1 side) of the switch 62, the terminal 40b, or a given position on a path connecting the end portion (the end portion opposite to the end portion on the node N1 side) of the switch 62 and the terminal 40b.

The low noise amplifier 10 is an example of an amplifier that amplifies a high-frequency signal, and is disposed in the amplification path 91. In the present embodiment, the low noise amplifier 10 amplifies a reception signal that is input from the antenna connection terminal 100 and transmitted through the amplification path 91. An input end of the low noise amplifier 10 is connected to the terminal 30a of the switch circuit 30 via the inductor 80. An output end of the low noise amplifier 10 is connected to the terminal 40c of the switch circuit 40.

The switch circuit 20 is connected between the antenna connection terminal 100 and the plurality of filters 51, 52, 53, and 54. The switch circuit 20 includes terminals 20a, 20b, 20c, 20d, and 20e. The terminal 20a is a common terminal and is connected to the antenna connection terminal 100. Each of the terminals 20b, 20c, 20d, and 20e is a selection terminal and is connected to a corresponding filter. The switch circuit 20 switches connection (conduction) and disconnection (non-conduction) between the terminal 20a and each of the terminals 20b, 20c, 20d, and 20e. The switch circuit 20 is implemented by a plurality of switching elements such as field effect transistors (FETs).

The switch circuit 30 is connected between the plurality of filters 51, 52, 53, and 54 and the amplification path 91. The switch circuit 30 includes the terminal 30a and terminals 30b, 30c, 30d, and 30e. The terminal 30a is a common terminal and is connected to the input terminal of the amplification path 91. Each of the terminals 30b, 30c, 30d, and 30e is a selection terminal. The switch circuit 30 switches connection (conduction) and disconnection (non-conduction) between the terminal 30a and each of the terminals 30b, 30c, 30d, and 30e. The switch circuit 30 is implemented by a plurality of switching elements such as FETs.

The switch circuit 40 is connected between the amplification path 91 and the bypass path 92, and the high-frequency output terminal 110. The switch circuit 40 includes a terminal 40a and the terminals 40b and 40c. The terminal 40a is a common terminal. Each of the terminals 40b and 40c is a selection terminal. The switch circuit 40 switches connection (conduction) and disconnection (non-conduction) between the terminal 40a and each of the terminals 40b and 40c. The switch circuit 40 is implemented by a plurality of switching elements such as FETs.

Each of the filters 51, 52, 53, and 54 is a reception filter whose pass band includes a downlink operation band of a predetermined communication band. The pass bands of the filters 51, 52, 53, and 54 are different from each other.

The communication band is, for example, a frequency division duplex (FDD) band or a time division duplex (TDD) band. The FDD band and the TDD band mean a frequency band predefined by a standardization organization (e.g., 3rd Generation Partnership Project (3GPP) (registered trademark) or Institute of Electrical and Electronics Engineers (IEEE)) for a communication system constructed using the radio access technology (RAT). In the present embodiment, as the communication system, for example, a 4th Generation-Long Term Evolution (4G-LTE) system, a 5th Generation-New Radio (5G-NR) system, a Wireless Local Area Network (WLAN) system, or the like can be used, but the communication system is not limited thereto.

The filter 51 has an input end connected to the terminal 20b of the switch circuit 20 and an output end connected to the terminal 30b of the switch circuit 30. The filter 52 has an input end connected to the terminal 20c of the switch circuit 20 and an output end connected to the terminal 30c of the switch circuit 30. The filter 53 has an input end connected to the terminal 20d of the switch circuit 20 and an output end connected to the terminal 30d of the switch circuit 30. The filter 54 has an input end connected to the terminal 20e of the switch circuit 20 and an output end connected to the terminal 30e of the switch circuit 30.

Each of the filters 51, 52, 53, and 54 is an acoustic wave filter. Specifically, each of the filters 51, 52, 53, and 54 is a filter having an acoustic wave resonator. The acoustic wave resonator is a surface acoustic wave (SAW) resonator, a bulk acoustic wave (BAW) resonator, or the like. The acoustic wave filter has a capacitive structure.

In the present embodiment, the amplifier circuit 1 includes the four filters 51, 52, 53, and 54, but the number of filters included in the amplifier circuit 1 is not limited thereto, and may be one to three, or five or more. The number of selection terminals of each of the switch circuits 20 and 30 is increased or decreased according to the number of filters. If the amplifier circuit 1 includes only one filter or no filter, the switch circuits 20 and 30 may be omitted. In this case, the input terminal of the amplification path 91 may be connected to the antenna connection terminal 100 via one filter, or may be directly connected to the antenna connection terminal 100.

The switch 61 is an example of a first switch and is connected in series to the bypass path 92. The switch 61 is referred to as a series switch. One end of the switch 61 is connected to the node N1, and the other end thereof is connected to the node N2. The node N2 is a branch point to a shunt path that connects the bypass path 92 and the ground, and is located between the switch 61 and the switch 62.

The switch 62 is an example of a second switch and is connected in series to the bypass path 92. The switch 62 is referred to as a series switch. The switch 62 is connected in series to the switch 61 on the bypass path 92. One end of the switch 62 is connected to a node N3, and the other end thereof is connected to the terminal 40b of the switch circuit 40. The node N3 is a branch point to a shunt path that connects the bypass path 92 and the ground, and is located between the switch 61 and the switch 62.

The switch 63 is an example of a third switch and is connected between the bypass path 92 and the ground. The switch 63 is referred to as a shunt switch. One end of the switch 63 is connected to the node N3, and the other end thereof is connected to the ground. In this embodiment, the switch 63 is connected between the capacitor 71 and the switch 62. That is, the node N3 to which one end of the switch 63 is connected is located between the capacitor 71 and the switch 62.

The switch 64 is an example of a fourth switch and is connected between the amplification path 91 and the ground. The switch 64 is referred to as a shunt switch. One end of the switch 64 is connected to a node N4, and the other end thereof is connected to the ground. The node N4 is a branch point to a shunt path that connects the amplification path 91 and the ground, and is located between the node N1 and the low noise amplifier 10. More specifically, the node N4 is located between the inductor 80 and the input end of the low noise amplifier 10. That is, the switch 64 is connected between the inductor 80 and the input end of the low noise amplifier 10.

The capacitor 71 is an example of a first capacitor, and at least one end thereof is connected between the switch 61 and the switch 62 of the bypass path 92. The capacitor 71 is connected in series to the bypass path 92. Specifically, one end of the capacitor 71 is connected to the node N2 (the other end of the switch 61), and the other end thereof is connected to the node N3 (one end of the switch 62).

The capacitor 72 is an example of a second capacitor and is connected between the bypass path 92 and the ground. One end of the capacitor 72 is connected to the node N2, and the other end thereof is connected to the ground. In this embodiment, the capacitor 72 is connected between the switch 61 and the capacitor 71. That is, the node N2 to which one end of the capacitor 72 is connected is located between the switch 61 and the capacitor 71.

The inductor 80 is connected in series to the amplification path 91 on the input side of the low noise amplifier 10. Specifically, one end of the inductor 80 is connected to the node N1, and the other end thereof is connected to the node N4.

The circuit configuration of the amplifier circuit 1 illustrated in FIG. 1 is an example, and is not limited thereto. For example, the switch circuit 40 may be omitted, and the output terminal of the bypass path 92 may be connected to the output side of the low noise amplifier 10 in the amplification path 91. Furthermore, for example, each of the output terminal of the amplification path 91 and the output terminal of the bypass path 92 may be directly connected to the high-frequency output terminal 110.

One of the capacitors 71 and 72 may be omitted. Also, the inductor 80 and the switch 64 may be omitted.

### 2. Operation

Next, the operation of the amplifier circuit 1 according to the present embodiment will be described.

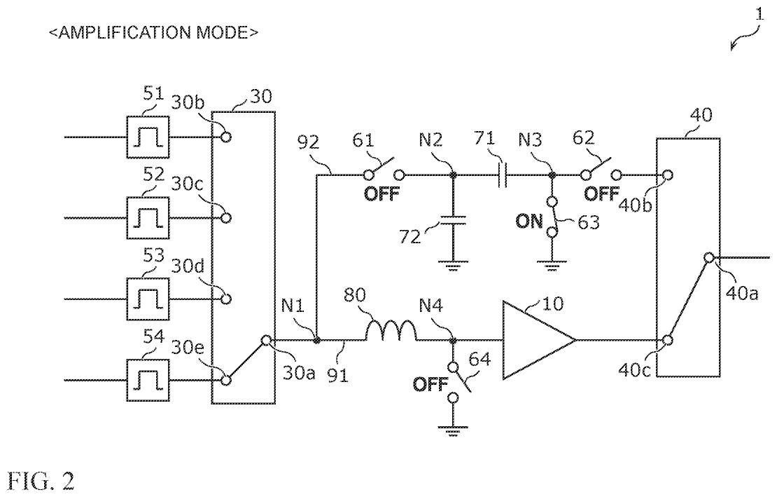

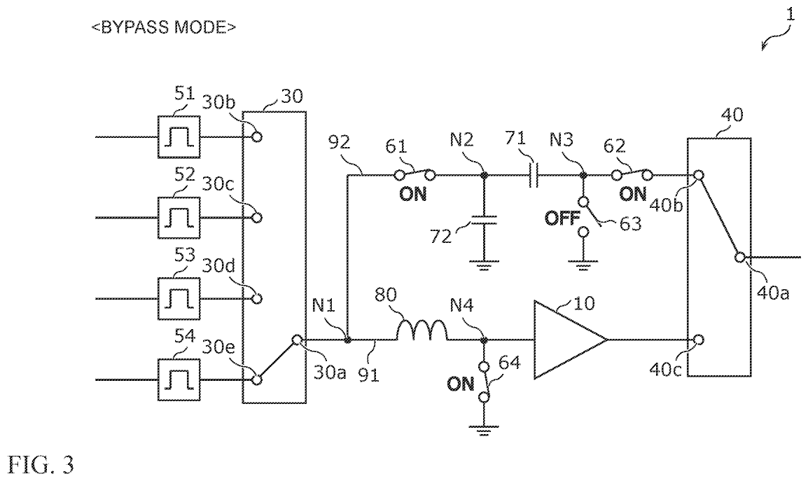

The amplifier circuit 1 according to the present embodiment has a plurality of operation modes. The plurality of operation modes include an amplification mode and a bypass mode. Hereinafter, the operation modes will be described with reference to FIGS. 2 and 3.

### 2.1 Amplification Mode

FIG. 2 is a circuit configuration diagram illustrating a circuit state of the amplification mode of the amplifier circuit 1 according to the present embodiment.

The amplification mode is an operation mode in which the low noise amplifier 10 amplifies a high-frequency signal. Specifically, in the amplification mode, a reception signal received by the antenna 2 and input from the antenna connection terminal 100 is transmitted through the amplification path 91 and output from the high-frequency output terminal 110.

As illustrated in FIG. 2, in the amplification mode, the switches 61, 62, and 64 are turned off (non-conductive), and the switch 63 is turned on (conductive). In the switch circuit 30, the terminal 30a is connected to any one of the terminals 30b, 30c, 30d, and 30e. FIG. 2 illustrates a case where a high-frequency signal passing through the filter 54 is amplified, and the terminal 30a is connected to the terminal 30e. In the switch circuit 40, the terminal 40a is connected to the terminal 40c.

Thus, in the signal path from the antenna connection terminal 100 to the high-frequency output terminal 110, the amplification path 91 functions as a transmission path, and the bypass path 92 is disconnected from the transmission path. The reception signal input from the antenna connection terminal 100 is transmitted through the amplification path 91, amplified by the low noise amplifier 10, and output from the high-frequency output terminal 110.

In the amplification mode, upon the switches 61 and 62 being turned off and the switch 63 being turned on, each of the capacitors 71 and 72 can be connected to the ground. In the amplification mode, the inductor 80 connected in series to the amplification path 91 is used to match the input impedance of the low noise amplifier 10.

In the amplification mode, upon the switches 61 and 62 being turned off, the bypass path 92 is disconnected from the amplification path 91. Accordingly, the inflow of the signal to the bypass path 92 is suppressed, and the signal loss can be reduced. Upon the switch 63 being turned on, the disconnected bypass path 92 can be connected to the ground. By stabilizing the potential of the bypass path 92, the influence on the amplification path 91 can be suppressed, and the noise of the high-frequency signal can be reduced.

### 2.2 Bypass Mode

FIG. 3 is a circuit configuration diagram illustrating a circuit state of the bypass mode of the amplifier circuit 1 according to the present embodiment.

The bypass mode is an operation mode in which the low noise amplifier 10 does not amplify a high-frequency signal. That is, in the bypass mode, a reception signal received by the antenna 2 and input from the antenna connection terminal 100 is transmitted through the bypass path 92 in which the low noise amplifier 10 is not provided, and output from the high-frequency output terminal 110.

As illustrated in FIG. 3, in the bypass mode, the switches 61, 62, and 64 are turned on (conductive), and the switch 63 is turned off (non-conductive). In the switch circuit 30, the terminal 30a is connected to any one of the terminals 30b, 30c, 30d, and 30e. FIG. 3 illustrates a case where a high-frequency signal passing through the filter 54 is amplified, and the terminal 30a is connected to the terminal 30e. In the switch circuit 40, the terminal 40a is connected to the terminal 40b.

Thus, in the signal path from the antenna connection terminal 100 to the high-frequency output terminal 110, the bypass path 92 functions as a transmission path. The reception signal input from the antenna connection terminal 100 is, without necessarily being amplified by the low noise amplifier 10, transmitted through the bypass path 92 and output from the high-frequency output terminal 110.

Note that the low noise amplifier 10 operates when a bias is supplied from a bias supply circuit (not illustrated), and does not operate when no bias is supplied. Accordingly, in the bypass mode, the bias is controlled not to be supplied to the low noise amplifier 10. However, it is difficult to completely turn off the low noise amplifier 10 to block the transmission of the signal, and a part of the signal may pass through the low noise amplifier 10. That is, a loop circuit of the bypass path 92 and the amplification path 91 is formed.

In this case, a sneak path of a signal from the output terminal of the amplification path 91 to the output terminal of the bypass path 92 may occur. In the present embodiment, since the switch circuit 40 is provided, it is possible to suppress the sneak path, but there may be a case where it is not possible to completely block the sneak path. In this case, the loss of the reception signal transmitted through the bypass path 92 or the generation of noise may occur.

On the other hand, upon the switch 64 being turned on in the bypass mode, the signal leaked from the bypass path 92 can be transmitted to the ground and can be prevented from being input to the low noise amplifier 10. That is, a loop circuit of the bypass path 92 and the amplification path 91 can be disconnected. Accordingly, the loss of the signal transmitted through the bypass path 92 can be suppressed.

Upon the switch 64 being turned on, the inductor 80 is connected to the node N1 and the ground and functions as a shunt inductor for the bypass path 92. Thus, the impedance of the bypass path 92 can be matched.

### 2.3 Switching of Operation Mode

The plurality of operation modes are switched, for example, by the RFIC 3 or the control unit that is not illustrated. For example, the amplification mode and the bypass mode are switched according to the power of the high-frequency signal transmitted through the amplifier circuit 1.

Specifically, if the power of the high-frequency signal is smaller than a predetermined value, the amplification mode is executed. As a result, the low noise amplifier 10 can amplify a weak high-frequency signal and output the amplified signal to the RFIC 3 from the high-frequency output terminal 110.

If the power of the high-frequency signal is larger than the predetermined value, the bypass mode is executed. For example, if the communication device 4 is close to a base station, the communication device 4 may receive a strong reception signal (a reception signal with large power). In this case, if the low noise amplifier 10 amplifies the reception signal, the reception signal may be distorted. By transmitting the reception signal with large power through the bypass path 92, it is possible to avoid the occurrence of signal distortion due to amplification.

In this way, by switching the operation mode according to the power of the high-frequency signal transmitted through the amplifier circuit 1, it is possible to suppress the occurrence of distortion of the high-frequency signal. Note that a switching condition of the operation mode is not limited to this. For example, the operation mode may be switched according to the communication band (frequency band) of the high-frequency signal.

### Effects

As described above, the amplifier circuit 1 according to the present embodiment includes the low noise amplifier 10 disposed in the amplification path 91, the switches 61 and 62 connected in series to the bypass path 92 bypassing the low noise amplifier 10, the capacitor 71 or 72 having at least one end connected between the switch 61 and the switch 62 in the bypass path 92, and the switch 63 connected between the bypass path 92 and the ground. The switch 63 is connected between the switch 61 and the switch 62.

Thus, if a high-frequency signal is transmitted through the bypass path 92, that is, in the bypass mode, the capacitor 71 or 72 can match the impedance between the input and output terminals of the bypass path 92. Accordingly, the loss of the high-frequency signal transmitted through the bypass path 92 can be reduced.

If a high-frequency signal is transmitted through the amplification path 91, that is, in the amplification mode, the bypass path 92 can be disconnected from the amplification path 91 by controlling the switches 61 and 62. Accordingly, the inflow of the signal to the bypass path 92 is suppressed, and the loss of the high-frequency signal transmitted through the amplification path 91 can be reduced.

Upon the switch 63 being controlled in the amplification mode, the disconnected bypass path 92 can be connected to the ground. By stabilizing the potential of the bypass path 92, the influence on the amplification path 91 can be suppressed, and the noise of the high-frequency signal can be reduced.

For example, the capacitor 71 is connected in series to the bypass path 92.

For example, the off capacitance of the switch circuit 30 serves as a shunt capacitance for the transmission path of a high-frequency signal. The impedance deviation caused by the shunt capacitance can be easily matched by the capacitor 71 connected in series to the bypass path 92.

For example, the amplifier circuit 1 includes the capacitor 72 connected between the bypass path 92 and the ground.

Thus, the range in which impedance matching can be achieved is widened. Accordingly, even if the impedance largely deviates due to the switch circuit 30 and the filters 51, 52, 53, and 54, the impedance can be matched.

For example, the capacitor 72 is connected between the switch 61 and the capacitor 71. The switch 63 is connected between the capacitor 71 and the switch 62.

Thus, without necessarily connecting an inductor to the bypass path 92, the impedance of the bypass path 92 can be matched. The signal loss due to the inductor can be suppressed.

For example, the amplifier circuit 1 includes the switch 64 connected between the amplification path 91 and the ground.

Thus, in the bypass mode, upon the switch 64 being turned on, a signal component leaked from the node N1 to the amplification path 91 can be propagated to the ground. Accordingly, it is possible to suppress the signal component that has leaked to the amplification path 91 from passing through the low noise amplifier 10 and re-flowing from the output terminal of the bypass path 92. In this way, since the loop circuit of the bypass path 92 and the amplification path 91 in the bypass mode can be disconnected, the signal loss can be reduced.

For example, the amplifier circuit 1 includes the inductor 80 connected in series to the amplification path 91 on the input side of the low noise amplifier 10. The switch 64 is connected between the inductor 80 and the input end of the low noise amplifier 10.

Thus, in the amplification mode, the inductor 80 functions as an element that matches the impedance of the amplification path 91 as a series inductor. Therefore, the signal loss in the amplification mode can be reduced. In the bypass mode, upon the switch 64 being turned on, the inductor 80 can function as a shunt inductor for the bypass path 92. For this reason, since the range in which impedance matching can be achieved is widened, the signal loss can be further reduced.

For example, the amplifier circuit 1 includes the switch circuit 30 connected to the input terminal of the amplification path 91.

Thus, the impedance between the switch circuit 30 and the bypass path 92 can be matched by the capacitor 71 or 72.

For example, the switch circuit 30 includes the terminal 30a, which is connected to the input terminal of the amplification path 91, and the plurality of terminals 30b, 30c, 30d, and 30e.

Thus, selection terminals that are not connected to the terminal 30a of the switch circuit 30 function as the off capacitance of the switch circuit 30, which causes the impedance of the bypass path 92 to deviate from a desired value (e.g., 50 Ω). For this reason, impedance matching by connecting the capacitor 71 or 72 to the bypass path 92 is more useful for reducing the signal loss.

For example, the amplifier circuit 1 includes the plurality of filters 51, 52, 53, and 54 connected to the plurality of terminals 30b, 30c, 30d, and 30e, respectively.

Thus, a filter through which a signal is allowed to pass can be selected, so that signals in a plurality of communication bands can be selectively transmitted.

For example, each of the plurality of filters 51, 52, 53, and 54 is an acoustic wave filter.

Thus, the acoustic wave filter has a capacitive structure, which causes the impedance of the bypass path 92 to deviate from a desired value (e.g., 50 Ω). For this reason, impedance matching by connecting the capacitor 71 or 72 to the bypass path 92 is more useful for reducing the signal loss.

For example, the amplifier circuit 1 may include an acoustic wave filter connected to the input terminal of the amplification path 91.

Even if the switch circuit 30 is not provided, the acoustic wave filter has a capacitive structure, which causes the impedance of the bypass path 92 to deviate from a desired value (e.g., 50 Ω). For this reason, impedance matching by connecting the capacitor 71 or 72 to the bypass path 92 is more useful for reducing the signal loss.

For example, the low noise amplifier 10 amplifies a reception signal transmitted through the amplification path 91.

Thus, the loss of the reception signal can be reduced.

The communication device 4 according to the present embodiment includes the amplifier circuit 1 and the RFIC 3 that processes a high-frequency signal transmitted through the amplifier circuit 1.

Thus, similarly to the above-described amplifier circuit 1, the loss of the high-frequency signal can be reduced.

### Miscellaneous

Although the amplifier circuit and the communication device according to the present disclosure have been described based on the above-described embodiment and the like, the present disclosure is not limited to the above-described embodiment.

For example, the capacitor 71 may be disconnected from the bypass path 92. In this case, the capacitor 72 connected between the bypass path 92 and the ground is an example of the first capacitor. That is, the first capacitor included in the amplifier circuit 1 may be a capacitor other than the series capacitor connected in series to the bypass path 92.

For example, the capacitor 72 may be connected between the capacitor 71 and the switch 63 in the bypass path 92. That is, the node N2 to which one end of the capacitor 72 is connected may be located between the capacitor 71 and the node N3.

Alternatively, the capacitor 72 may be connected between the switch 63 and the switch 62 in the bypass path 92. That is, the node N2 to which one end of the capacitor 72 is connected may be located between the node N3 and the switch 62.

The switch 63 may be connected between the switch 61 and the capacitor 72 in the bypass path 92. That is, the node N3 to which one end of the switch 63 is connected may be located between the switch 61 and the node N2.

The switch 63 may be connected between the capacitor 72 and the capacitor 71 in the bypass path 92. That is, the node N3 to which one end of the switch 63 is connected may be located between the node N2 and the capacitor 71.

For example, each of the filters 51, 52, 53, and 54 may be an LC filter.

For example, the amplifier circuit 1 may include a power amplifier that amplifies a transmission signal instead of the low noise amplifier 10. The amplifier circuit 1 may include an amplification path to which the power amplifier is connected and a bypass path bypassing the power amplifier.

Other forms obtained by applying various modifications conceived by those skilled in the art to each of the embodiments, and other forms implemented by freely combining structural elements and functions in each of the embodiments without necessarily departing from the spirit of the present disclosure, are also included in the present disclosure.

Features of the amplifier circuit and the communication device described based on each of the embodiments will be described below.

<1>

An amplifier circuit including:
an amplifier disposed in a first path;
a first switch and a second switch connected in series to a second path bypassing the amplifier;
a first capacitor having at least one end connected between the first switch and the second switch in the second path; and
a third switch connected between the second path and a ground, in which
the third switch is connected between the first switch and the second switch.
   <2>

The amplifier circuit according to <1>, in which the first capacitor is connected in series to the second path.

<3>

The amplifier circuit according to <1>or <2>, including:
a second capacitor connected between the second path and the ground.
   <4>

The amplifier circuit according to <3>, in which
the second capacitor is connected between the first switch and the first capacitor, and
the third switch is connected between the first capacitor and the second switch.
   <5>

The amplifier circuit according to any one of <1>to <4>, including:
a fourth switch connected between the first path and the ground.
   <6>

The amplifier circuit according to <5>, including:
an inductor connected in series to the first path on an input side of the amplifier, in which
the fourth switch is connected between the inductor and an input end of the amplifier.
   <7>

The amplifier circuit according to any one of <1>to <6>, including:
a switch circuit connected to an input terminal of the first path.
   <8>

The amplifier circuit according to <7>, in which the switch circuit comprises a common terminal and a plurality of selection terminals, the common terminal being connected to the input terminal of the first path.

<9>

The amplifier circuit according to <8>, including:
a plurality of filters each connected to a corresponding one of the plurality of selection terminals.
   <10>

The amplifier circuit according to <9>, in which the plurality of filters are each an acoustic wave filter.

<11>

The amplifier circuit according to any one of <1>to <6>, including:
an acoustic wave filter connected to an input terminal of the first path.
   <12>

The amplifier circuit according to any one of <1>to <11>, in which the amplifier is a low noise amplifier that amplifies a reception signal transmitted through the first path.

<13>

A communication device including:
the amplifier circuit according to any one of <1>to <12>; and
a radio frequency (RF) signal processing circuit that process a high-frequency signal transmitted through the amplifier circuit.

The present disclosure can be widely used as a multiband/multimode compatible front end circuit or the like in a communication device such as a cellular phone.

What is claimed is:

1. An amplifier circuit comprising:
an amplifier in a first path;
a first switch and a second switch connected in series in a second path, the second path bypassing the amplifier;
a first capacitor having at least a first end connected between the first switch and the second switch in the second path; and
a third switch connected between the second path and ground,
wherein the third switch has a first end that is connected between the first switch and the second switch.

2. The amplifier circuit according to claim 1, wherein the first capacitor is connected in series in the second path.

3. The amplifier circuit according to claim 2, comprising:
a second capacitor connected between the second path and ground.

4. The amplifier circuit according to claim 3,
wherein the second capacitor has a first end that is connected between the first switch and the first capacitor, and
wherein the first end of the third switch is connected between the first capacitor and the second switch.

5. The amplifier circuit according to claim 1, comprising:
a fourth switch connected between the first path and the ground.

6. The amplifier circuit according to claim 5,
an inductor connected in series in the first path on an input side of the amplifier,
wherein a first end of the fourth switch is connected between the inductor and an input of the amplifier.

7. The amplifier circuit according to claim 1, comprising:
a switch circuit connected to an input terminal of the first path.

8. The amplifier circuit according to claim 7, wherein the switch circuit comprises a common terminal and a plurality of selection terminals, the common terminal being connected to the input terminal of the first path.

9. The amplifier circuit according to claim 8, comprising:
a plurality of filters each connected to a corresponding one of the plurality of selection terminals.

10. The amplifier circuit according to claim 9, wherein the plurality of filters are each an acoustic wave filter.

11. The amplifier circuit according to claim 1, comprising:
an acoustic wave filter connected to an input terminal of the first path.

12. The amplifier circuit according to claim 1, wherein the amplifier is a low noise amplifier configured to amplify a reception signal passed through the first path.

13. A communication device comprising:
the amplifier circuit according to claim 1; and
a radio frequency (RF) signal processing circuit configured to process a high-frequency signal passed through the amplifier circuit.

14. The amplifier circuit according to claim 5, wherein the fourth switch is in a disconnected state, the first and second switches are in a disconnected state, and the third switch is in a connected state.

15. The amplifier circuit according to claim 5, wherein the fourth switch is in a connected state, the first and second switches are in a connected state, and the third switch is in a disconnected state.

16. The amplifier circuit according to claim 1, comprising:
a switch circuit connected to output terminals of the first and second paths.

17. The amplifier circuit according to claim 16, wherein the switch circuit comprises a common terminal and first and second selection terminals, the first selection terminal being connected to an output terminal of the first path and the second selection terminal being connected to an output terminal of the second path.
